(19) United States
(12) Patent Application Publication
(10) Pub. No.: US 2025/0262707 A1
(43) Pub. Date: Aug. 21, 2025

(54) GRINDING APPARATUS

(71) Applicant: Tokyo Seimitsu Co., Ltd., Tokyo (JP)

(72) Inventor: Taira TSURU, Tsuchiura-shi (JP)

(21) Appl. No.: 19/059,368

(22) Filed: Feb. 21, 2025

(30) Foreign Application Priority Data
Feb. 21, 2024 (JP) 2024-024704

(51) Int. Cl. B24B 9/06; B24B 49/02; H01J 37/32

(52) U.S. Cl. CPC B24B 9/065; B24B 49/02; H01J 37/32385; H01J 2237/24585

(57) ABSTRACT

To make an improvement in the shape accuracy of a wafer shaped in the grinding operation after pretreatment and make an improvement in the efficiency of grinding operation of a wafer. A grinding apparatus includes at least one plasma generator configured to irradiate, before an outer circumferential edge of a wafer is ground, at least part of the outer circumferential edge with plasma.

### CROSS-REFERENCE TO RELATED APPLICATION

This application claims the benefit of Japanese Application No. 2024-024704, filed Feb. 21, 2024, the disclosure of which is incorporated by reference herein in its entirety.

### BACKGROUND OF THE INVENTION

### 1. Field of the Invention

The present invention relates to a grinding apparatus.

### 2. Description of the Related Art

A wafer produced from a monocrystalline raw material is used to produce a semiconductor. In particular, a silicon carbide (SiC) wafer produced from monocrystalline SiC is used to produce a SiC semiconductor. In a process of producing such a SiC semiconductor, a step of growing an epitaxial thin film on a SiC wafer (epitaxial growth step) is performed, so that a SiC epitaxial wafer is produced.

However, a defect occurs easily at the outer circumferential portion of such a SiC epitaxial wafer, and thus a grinding technique is used to grind the outer circumferential portion of a SiC wafer in a step before the epitaxial growth step. An example of such a grinding technique is a technique as disclosed in Japanese Patent Application Laid-open No. 2016-032002, in which the outer circumferential end of a SiC wafer is rough-polished by a grindstone such as a metal bonded grindstone and then the outer circumferential end of the SiC wafer is finish-polished by a grindstone such as a resin bonded grindstone.

### SUMMARY OF THE INVENTION

However, in the above exemplary grinding technique, a SiC wafer to be subjected to rough polishing is a hard-to-cut material and has a sharp edge. A grindstone used to rough-polish such a SiC wafer abrades easily and further repetition of rough polishing is likely to cause a change in the shape of the grindstone.

Due to such a change in the shape of the grindstone for rough polishing, the shape accuracy of the SiC wafer is likely to deteriorate after rough polishing shaped by the grindstone. Furthermore, the shape accuracy of the SiC wafer is likely to deteriorate after finish polishing. In addition, due to a change in the shape of the grindstone for rough polishing, the operation of maintenance, such as replacement of the grindstone, is required to be frequently performed. This causes a deterioration in operation efficiency of grinding a SiC wafer.

In consideration of such a situation, embodiments of the present invention provide a grinding apparatus enabling an improvement in the shape accuracy of a wafer shaped due to the grinding operation and an improvement in operation efficiency of grinding a wafer.

Embodiments of the present invention to address the above-described problems are as follows.
[1] A grinding apparatus including at least one plasma generator configured to irradiate, before an outer circumferential edge of a wafer is ground, at least part of the outer circumferential edge with plasma.
[2] The grinding apparatus according to [1], in which the plasma generator includes a plurality of plasma generators, the plasma generators each include a nozzle configured to emit the plasma, and the nozzles of the plasma generators face two edge portions in a thickness direction of the outer circumferential edge of the wafer in one-to-one correspondence to irradiate the two edge portions with the plasma.
[3] The grinding apparatus according to [2], in which the nozzles of the plasma generators are each provided inclinably.
[4] The grinding apparatus according to [1], further including: a swiveling device for swiveling the wafer around a central axis of the wafer; and a grinder including a grinding wheel configured to grind an outer circumferential portion of the wafer, and a driver configured to swivel the grinding wheel, in which the plasma generator is capable of irradiating, with the plasma, a pretreatment target that moves in a circumferential direction of the wafer due to swiveling of the wafer around the central axis.
[5] The grinding apparatus according to [4], further including: a controller; and an arithmetic device capable of calculating at least either an optimum condition for irradiation with the plasma by the plasma generator or an optimum condition for grinding by the grinder, in which the controller is capable of controlling at least one of the plasma generator and the grinder to meet at least either the optimum condition for irradiation with the plasma or the optimum condition for grinding, calculated by the arithmetic device.
[6] The grinding apparatus according to [5], further including a surface inspection device capable of inspecting a surface state of the wafer, in which the arithmetic device is capable of calculating, as the optimum condition for irradiation with the plasma, an optimum value for at least one of a diameter and power of the plasma and a swiveling rate of the wafer, based on data regarding the surface state, and the controller is capable of controlling the plasma generator and the swiveling device to meet the optimum value.
[7] The grinding apparatus according to [5], further including at least either a shape inspection device capable of inspecting a shape of the wafer or a crystal inspection device capable of inspecting a crystal state of the wafer, in which the arithmetic device is capable of calculating, as the optimum condition for grinding, an optimum value for at least one of a depth of infeed and a swiveling rate of the grinding wheel and a swiveling rate of the wafer, based on at least either the shape or the crystal state, and the controller is capable of controlling the grinder and the swiveling device to meet the optimum value.
[8] The grinding apparatus according to [4], including the plasma generators mutually spaced in a circumferential direction of the wafer.

### BRIEF DESCRIPTION OF THE DRAWINGS

FIG. 1 is a block diagram of a grinding apparatus according to a first embodiment;

FIG. 2 is a schematic plan view of main parts of the grinding apparatus according to the first embodiment;

FIG. 3 is a view in the direction of an arrow V of FIG. 2;

FIG. 4 is a view in the direction of an arrow W of FIG. 2;

FIG. 5 is a sectional view taken along line X-X of FIG. 2;

FIG. 6 is a sectional view taken along line Y-Y of FIG. 2;

FIG. 7 is a sectional view taken along line Z-Z of FIG. 2;

FIG. 8 is a flowchart for describing a grinding method using the grinding apparatus according to the first embodiment;

FIG. 9 is a flowchart for describing a method for optimizing the condition for irradiation with plasma by a pretreatment device in the grinding apparatus according to the first embodiment;

FIG. 10 is a flowchart for describing a method for optimizing the condition for grinding in the grinding apparatus according to the first embodiment;

FIG. 11 is a schematic plan view of main parts of a grinding apparatus according to a second embodiment;

FIG. 12 is a block diagram of a grinding apparatus according to a third embodiment;

FIG. 13 is a schematic plan view of main parts of the grinding apparatus according to the third embodiment;

FIG. 14 is a sectional view schematically illustrating a state where two edge portions in the outer circumferential portion of a wafer are each irradiated with plasma in the third embodiment; and

FIG. 15 is a schematic plan view of a grinding apparatus according to a fourth embodiment.

### DETAILED DESCRIPTION OF EMBODIMENTS

Respective grinding apparatuses according to first to fourth embodiments will be described below.

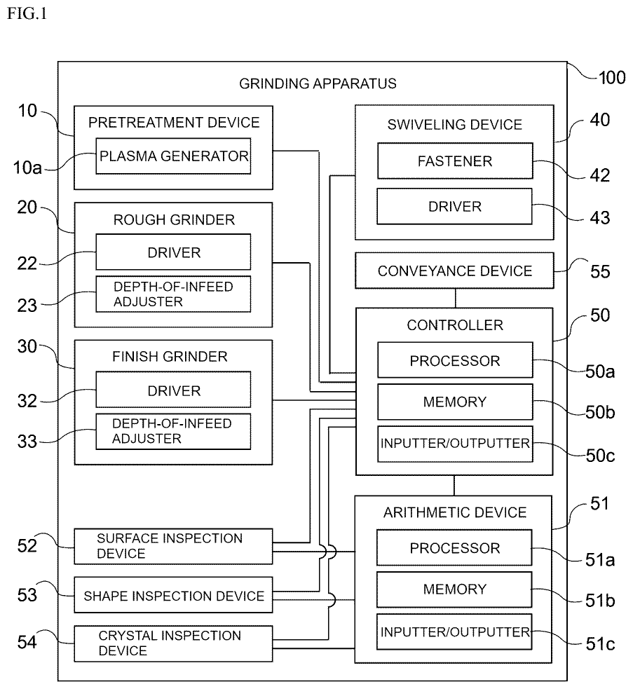

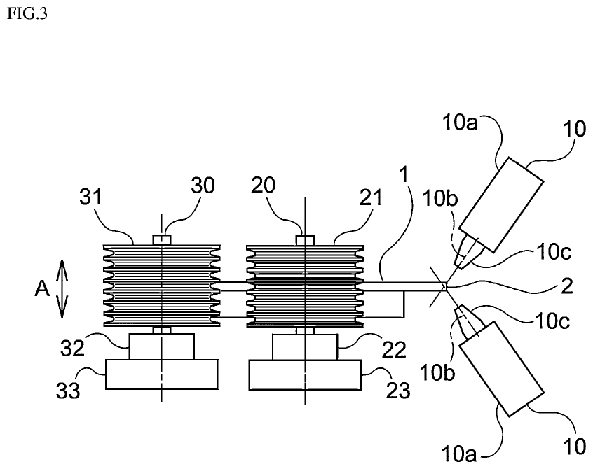

The grinding apparatus according to the first embodiment will be described below with reference to FIGS. 1 to 9. Referring to FIGS. 1 to 7, the grinding apparatus according to the present embodiment is roughly configured as follows.

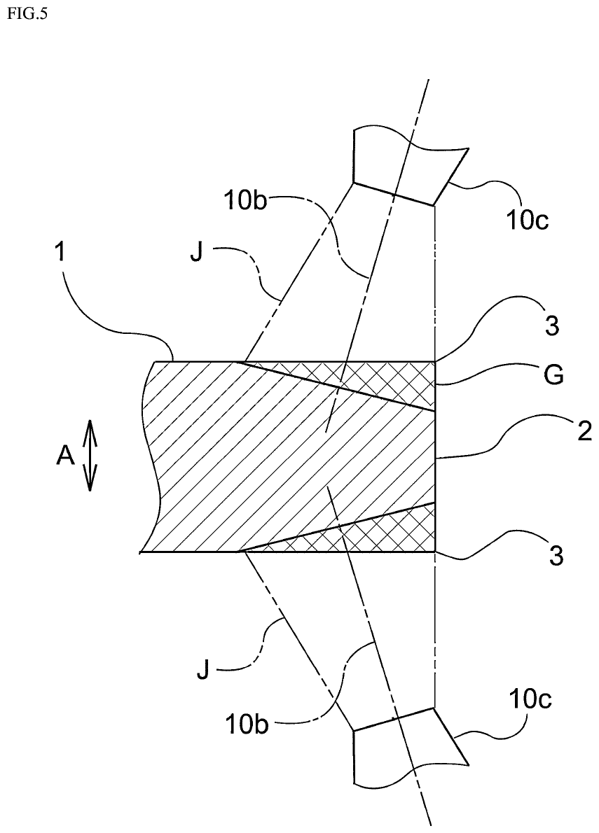

Referring to FIGS. 1 to 5, for grinding an outer circumferential portion 2 of a disk-shaped wafer 1, a grinding apparatus 100 according to the present embodiment enables plasma irradiation, as a treatment before grinding with a grindstone, to a treatment target G (indicated with shading in a lattice pattern in FIG. 5) that is at least part of the outer circumferential portion 2 of the wafer 1. In other words, the grinding apparatus 100 enables plasma-assisted grinding. The grinding apparatus 100 includes a pretreatment device 10 including a plasma generator 10a capable of irradiating the treatment target G with plasma J to modify the treatment target G.

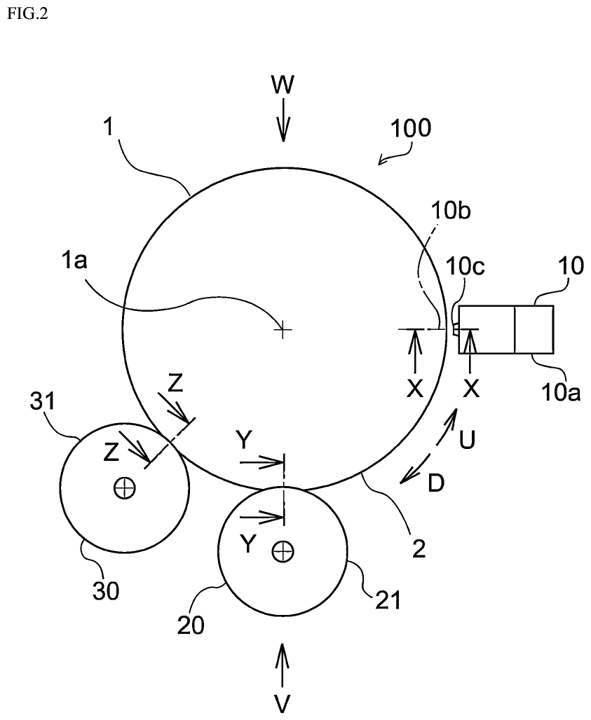

As illustrated in FIGS. 2 to 5, the grinding apparatus 100 includes two plasma generators 10a. Each plasma generator 10a includes a nozzle 10c capable of emitting plasma J outward along its irradiation axis 10b. However, the grinding apparatus 100 can include a single plasma generator or three or more plasma generators.

The wafer 1 serves as a silicon carbide (SiC) wafer 1. As illustrated in FIG. 5, the outer circumferential portion 2 of the wafer 1 includes, as the treatment target G, two edge portions 3 located one-to-one at both ends in the direction of the central axis of the wafer 1 (indicated with a double-headed arrow A). The respective nozzles 10c of the two plasma generators 10a are disposed facing one-to-one the two edge portions 3 such that the two edge portions 3 can be irradiated one-to-one with the plasma J from one of the two plasma generators 10a and with the plasma J from the other.

In the wafer 1, each edge portion 3 has a shape identical to a shape to be removed by chamfering. The two plasma generators 10a are mutually spaced in the direction of the central axis of the wafer 1. The nozzle 10c of each plasma generator 10a is disposed with its irradiation axis 10b at an angle such that the facing edge portion 3 can be irradiated with the plasma J corresponding to the shape of the facing edge portion 3.

Next, referring to FIGS. 1 to 7, the grinding apparatus 100 according to the present embodiment is roughly configured as follows. As illustrated in FIGS. 1 to 5, the grinding apparatus 100 includes the above-described pretreatment device 10. The plasma generator 10a of the pretreatment device 10 is capable of irradiating, with the plasma J, the treatment target G that moves in the circumferential direction of the wafer 1 (indicated with two single-headed arrows U and D) due to swiveling of the wafer 1 around its central axis 1a.

As illustrated in FIGS. 1 to 4 and FIGS. 6 and 7, the grinding apparatus 100 includes two grinders (rough grinder 20 and finish grinder 30) capable of grinding the outer circumferential portion 2 of the wafer 1. One of the two grinders and the other include, respectively, a grinding wheel 21 and a grinding wheel 31 capable of grinding the outer circumferential portion 2 of the wafer 1 that moves from one side (indicated with the single-headed arrow U in FIG. 2) to the other side (indicated with the single-headed arrow D in FIG. 2) in the circumferential direction of the wafer 1 due to swiveling of the wafer 1. The one of the two grinders and the other include, respectively, a driver 22 and a driver 32 capable of swiveling, respectively, the grinding wheel 21 and the grinding wheel 31 counter to the movement of the wafer 1.

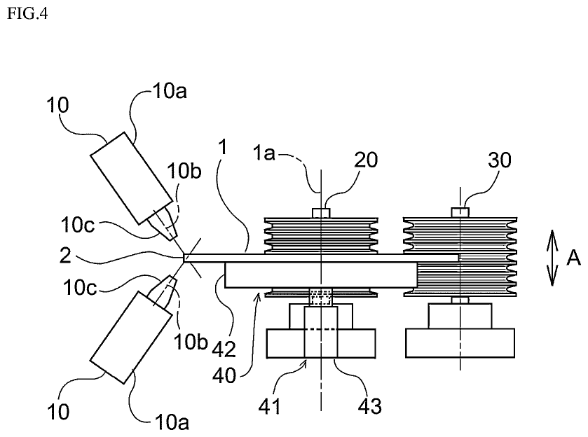

As illustrated in FIGS. 1 and 4, the grinding apparatus 100 includes a swiveling device 40 for swiveling the wafer 1 around the central axis 1a at the time of pretreatment of the wafer 1 by the pretreatment device 10 or at the time of grinding of the wafer 1 by the grinders. As illustrated in FIG. 1, the grinding apparatus 100 includes a controller 50 capable of controlling the pretreatment device 10, the grinders, and the swiveling device 40.

The grinding apparatus 100 includes an arithmetic device 51 capable of calculating at least either an optimum condition for irradiation with the plasma J by the pretreatment device 10 or an optimum condition for grinding by the grinders. The controller 50 is capable of controlling at least one of the pretreatment device 10 (plasma generator), the grinders, and the swiveling device 40 to meet at least either the optimum condition for irradiation with the plasma J or the optimum condition for grinding, calculated by the arithmetic device 51.

The grinding apparatus 100 includes a surface inspection device 52 capable of inspecting the surface state of the treatment target G modified by the pretreatment device 10. On the basis of data regarding the surface state of the treatment target G obtained by the surface inspection device 52, the arithmetic device 51 is capable of calculating, as the optimum condition for irradiation with the plasma J, an optimum value for at least one of the power and diameter of the plasma J and the swiveling rate of the wafer 1. The controller 50 is capable of controlling the pretreatment device 10 (plasma generator) and the swiveling device 40 to meet the optimum value for at least one of the power and diameter of the plasma J and the swiveling rate of the wafer 1, calculated by the arithmetic device 51.

The grinding apparatus 100 includes at least either a shape inspection device 53 capable of inspecting the shape of the wafer 1 ground by the grinders or a crystal inspection device 54 capable of inspecting the crystal state of the wafer 1 ground by the grinders.

On the basis of at least either data regarding the shape of the wafer 1 obtained by the shape inspection device 53 or data regarding the crystal state of the wafer 1 obtained by the crystal inspection device 54, the arithmetic device 51 is capable of calculating, as the optimum condition for grinding, an optimum value for at least one of the depth of infeed and swiveling rate of each of the grinding wheels 21 and 31 and the swiveling rate of the wafer 1. The controller 50 is capable of controlling the grinders and the swiveling device 40 to meet the optimum value for at least one of the depth of infeed and swiveling rate of each of the grinding wheels 21 and 31 and the swiveling rate of the wafer 1, calculated by the arithmetic device 51.

As illustrated in FIG. 4, the swiveling device 40 includes a swiveling mechanism 41 that swivels the wafer 1 around the central axis 1a at a certain position at the time of pretreatment of the wafer 1 by the pretreatment device 10 or at the time of grinding of the wafer 1 by the grinders. The pretreatment device 10 is disposed on one side in the circumferential direction of the wafer 1 with respect to the grinders.

However, the swiveling device is not limited to this. For example, the swiveling device can separately include a swiveling mechanism for pretreatment that swivels the wafer around its central axis at the time of pretreatment of the wafer by the pretreatment device and a swiveling mechanism for grinding that swivels the wafer around its central axis at the time of grinding of the wafer by the grinders. In this case, the swiveling mechanism for pretreatment and the swiveling mechanism for grinding are disposed away from each other. In addition, the wafer can be conveyed between the swiveling mechanism for pretreatment and the swiveling mechanism for grinding by a conveyance device described later.

Specifically, the wafer 1 as a target to be processed can be provided as follows. The type of the wafer 1 will be described. First, as described above, a SiC wafer 1 can be used as the wafer 1. That is, SiC can be used as the raw material of the wafer 1. In particular, as the raw material of the SiC wafer, 4H-SiC, 6H-SiC, 3C-SiC, or the like can be used. However, as the raw material of the wafer, silicon (Si), gallium arsenide (GaAs), or the like can be used.

As illustrated in FIG. 5, the treatment target G of the wafer 1 includes two edge portions 3 in the outer circumferential portion 2 of the wafer 1. In a case where a section of the outer circumferential portion 2 of the wafer 1 taken along the central axis 1a of the wafer 1 is viewed, the range of each edge portion 3 can be regarded as a substantially triangular range. The range of each edge portion 3 can be defined as a range surrounded by a first side along one face in the direction of the central axis of the wafer 1, a second side along the outer circumferential face of the wafer 1, and a third side that extends inside the wafer 1 and connects the one face and the outer circumferential face.

Referring to FIGS. 1 to 5, specifically, the grinding apparatus 100 according to the present embodiment can be provided as follows. In the grinding apparatus 100, the plasma generators 10a each serve as a plasma jet generator. The plasma generators 10a as above are capable of irradiation with a water vapor plasma jet under atmospheric pressure. However, the plasma generators are not limited to such a plasma jet generator. For example, the plasma generators may be each a plasma torch.

The treatment target G irradiated with the plasma J by each plasma generator 10a is modified as follows. In a case where the raw material of the wafer 1 is SiO, particularly, 4H-SiO, OH radicals are generated as reactive species in response to plasma irradiation to the treatment target G of the wafer 1 by each plasma generator 10a. Due to such hydroxyl (OH) radicals, the treatment target G is modified to SiO2. In this case, the treatment target G softens as a result.

The plasma generators 10a can be each configured to perform raster scanning such that scanning with the plasma J along the radial direction of the wafer 1 is performed all over the edge portion 3 facing its nozzle 10c. In this case, the position of arrangement of each nozzle 10c, the power and diameter of the plasma J from each nozzle 10c, and the swiveling rate of the wafer 1 can be adjusted as appropriate to accurately modify the entirety of the edge portion 3 facing the corresponding nozzle 10c.

The plasma J for irradiation from the nozzle 10c of each plasma generator 10a is emitted along the irradiation axis 10b. The irradiation axis 10b is substantially identical to the central axis of the plasma J. Furthermore, the pretreatment device 10 is configured to allow simultaneous emission of plasma J from two plasma generators 10a. Due to the two plasma generators 10a, two edge portions 3 can be simultaneously irradiated with the plasma J. As an example, the maximum output of each plasma generator 10a can be set to approximately 1.5 kW.

Next, referring to FIGS. 1 to 7, specifically, the grinding apparatus 100 according to the present embodiment can be configured as follows. The grinding apparatus 100 includes two grinders.

As illustrated in FIGS. 1 to 4 and FIG. 6, one of the two grinders serves as the rough grinder 20 capable of rough-grinding the outer circumferential portion 2 of the wafer 1 pretreated by the pretreatment device 10. As illustrated in FIGS. 1 to 4 and FIG. 7, the other of the two grinders serves as the finish grinder 30 (precision grinder) capable of finish-grinding the outer circumferential portion 2 of the wafer 1 rough-ground by the rough grinder 20. As illustrated in FIG. 2, the rough grinder 20 is located on one side (indicated with the single-headed arrow U) in the rotational direction of the wafer 1 with respect to the finish grinder 30.

As illustrated in FIGS. 2 to 4 and FIG. 6, the rough grinder 20 includes the grinding wheel 21 capable of rough-grinding the outer circumferential portion 2 of the wafer 1 after pretreatment by the pretreatment device 10. The grinding wheel 21 is formed such that at least the two edge portions 3 in the outer circumferential portion 2 of the wafer 1 can be ground. At the time of rough grinding by the rough grinder 20, the outer circumferential portion 2 of the wafer 1 moves from one side to the other side in the circumferential direction of the wafer 1 due to swiveling of the wafer 1.

As illustrated in FIGS. 1 to 4 and FIG. 6, the rough grinder 20 includes the driver 22 capable of swiveling the grinding wheel 21 counter to the movement of the wafer 1. The rough grinder 20 can include a depth-of-infeed adjuster 23 capable of adjusting the depth of infeed of the grinding wheel 21 to the outer circumferential portion 2 of the wafer 1. The depth-of-infeed adjuster 23 is configured such that the grinding wheel 21 is movable in a direction closer to the wafer 1 and in a direction away from the wafer 1.

For example, the depth-of-infeed adjuster 23 as above can operate the grinding wheel 21 to move away from the outer circumferential portion 2 of the wafer 1 before the treatment target G of the outer circumferential portion 2 of the wafer 1 is irradiated with the plasma J by the pretreatment device 10 and operate the grinding wheel 21 to rough-grind the outer circumferential portion 2 of the wafer 1 after the treatment target G of the outer circumferential portion 2 of the wafer 1 is irradiated with the plasma J by the pretreatment device 10.

As illustrated in FIGS. 2 to 4 and FIG. 7, the finish grinder 30 includes the grinding wheel 31 capable of finish-grinding the outer circumferential portion 2 of the wafer 1 after rough grinding by the rough grinder 20. The grinding wheel 31 is formed corresponding to a finished shape for the outer circumferential portion 2 of the wafer 1. At the time of finish grinding by the finish grinder 30, the outer circumferential portion 2 of the wafer 1 moves from one side to the other side in the circumferential direction of the wafer 1 due to swiveling of the wafer 1. Note that the finish grinder 30 may be a helical grinder that performs grinding with the grinding wheel 31 having a rotation axis at an angle to the rotation axis of the wafer 1.

As illustrated in FIGS. 1 to 4 and FIG. 7, the finish grinder 30 includes the driver 32 capable of swiveling the grinding wheel 31 counter to the movement of the wafer 1. The finish grinder 30 can include a depth-of-infeed adjuster 33 capable of adjusting the depth of infeed of the grinding wheel 31 to the outer circumferential portion 2 of the wafer 1. The depth-of-infeed adjuster 33 is configured such that the grinding wheel 31 is movable in a direction closer to the wafer 1 and in a direction away from the wafer 1.

For example, the depth-of-infeed adjuster 33 as above can operate the grinding wheel 31 to move away from the outer circumferential portion 2 of the wafer 1 before the outer circumferential portion 2 of the wafer 1 is rough-ground by the rough grinder 20 and operate the grinding wheel 31 to finish-grind the outer circumferential portion 2 of the wafer 1 after the outer circumferential portion 2 of the wafer 1 is rough-ground by the rough grinder 20.

As illustrated in FIGS. 1 and 4, in the grinding apparatus, the swiveling mechanism 41 of the swiveling device 40 includes a fastener 42 capable of fixing the wafer 1. The fastener 42 is configured such that a switch can be made between a state where the wafer 1 is fixed and a state where the fixation of the wafer 1 is released. The swiveling mechanism 41 includes a driver 43 capable of swiveling the fastener 42 together with the wafer 1 around the central axis 1a of the wafer 1.

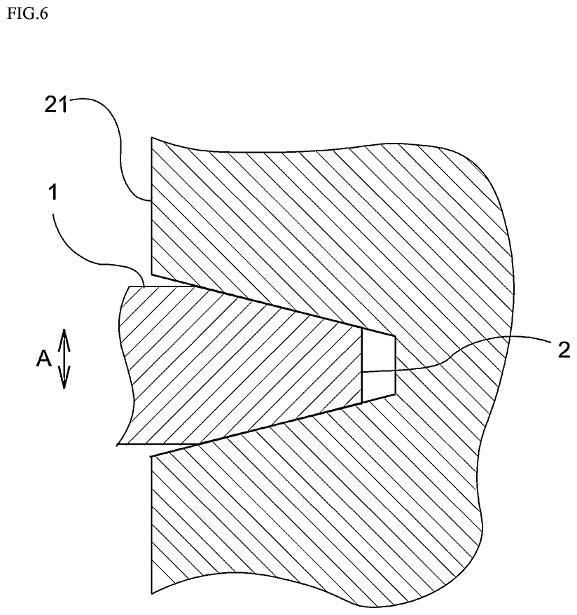

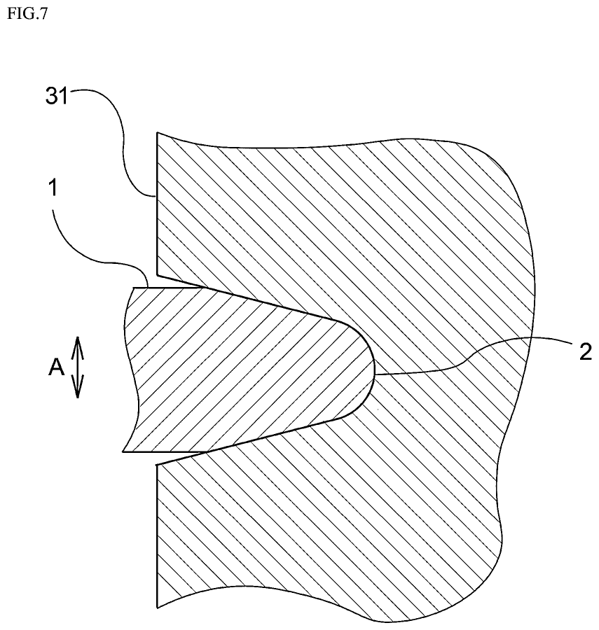

As illustrated in FIG. 5, the treatment target G of the outer circumferential portion 2 of the wafer 1 that swivels due to the swiveling mechanism 41 as above is irradiated with the plasma J from the pretreatment device 10. Due to such irradiation, the treatment target G extending over the entire circumference of the outer circumferential portion 2 of the wafer 1 is modified. Furthermore, as illustrated in FIGS. 6 and 7, the entirety of the outer circumferential portion 2 of the wafer 1 that swivels due to the swiveling mechanism 41 is ground by the two grinders.

As illustrated in FIG. 1, the controller 50 includes a processor 50a, a memory 50b, and an inputter/outputter 50c. The processor 50a is an integrated circuit for control. For example, as the processor 50a, a central processing unit (CPU) or a microcontroller can be used. The processor 50a can include a random access memory (RAM) for working, not illustrated.

The memory 50b is a general information storage medium. As the memory 50b, a nonvolatile memory can be used. For example, as the memory 50b, a read only memory (ROM), an electrically erasable programmable read only memory (EEPROM), a flash memory, or a hard disk can be used. The memory 50b can store programs, various types of data, and the like.

The inputter/outputter 50c serves as an interface for electrically connecting the controller 50 to the pretreatment device 10, the two grinders, the swiveling device 40, and the arithmetic device 51. The inputter/outputter 50c also serves as an interface for electrically connecting the controller 50 to the surface inspection device 52. Furthermore, the inputter/outputter 50c serves as an interface for electrically connecting the controller 50 to at least either the shape inspection device 53 or the crystal inspection device 54.

The arithmetic device 51 can include a processor 51a, a memory 51b, and an inputter/outputter 51c, similarly to the controller 50. The arithmetic device 51 can include a machine learning model for pretreatment inspection that is capable of calculating an optimum value for at least one of the power and diameter of the plasma J and the swiveling rate of the wafer 1, on the basis of data regarding the surface state of the treatment target G obtained by the surface inspection device 52.

Note that the above machine learning model can be generated on the basis of a data set (training data set) including a plurality of entries each including the pretreatment condition for the wafer (the power and diameter of the plasma J and the swiveling rate of the wafer 1) and the resultant surface state in association.

However, the arithmetic device is not limited to including such a machine learning model for pretreatment inspection. For example, the arithmetic device can perform statistical analysis for pretreatment inspection to calculate an optimum value for at least one of the power and diameter of the plasma and the swiveling rate of the wafer 1, on the basis of data regarding the surface state of the pretreatment target obtained by the surface inspection device.

The arithmetic device 51 includes a machine learning model for grinding evaluation that is capable of calculating an optimum value for at least one of the depth of infeed and swiveling rate of each of the grinding wheels 21 and 31 and the swiveling rate of the wafer 1, on the basis of at least either data regarding the shape of wafer 1 obtained by the shape inspection device 53 (e.g., shape dimensions and surface roughness) or data regarding the crystal state of the wafer 1 obtained by the crystal inspection device 54.

However, the arithmetic device 51 is not limited to including such a machine learning model for grinding evaluation. For example, the arithmetic device 51 can perform statistical analysis for pretreatment inspection to calculate an optimum value for at least one of the power and diameter of the plasma and the swiveling rate of the wafer 1, on the basis of data regarding the surface state of the pretreatment target obtained by the surface inspection device 52.

The surface inspection device 52 can be configured to perform, for example, X-ray photoelectron spectroscopy (XPS) analysis or transmission electron microscope (TEMS)/scanning transmission electron microscope (STEM) analysis to the treatment target G after irradiation with the plasma J. Due to the surface inspection device 52 as above, the elementary composition and chemical bond state of the treatment target G after irradiation with the plasma J can be measured. That is, the surface state obtained by the surface inspection device 52 can be regarded as the elementary composition and chemical bond state.

The shape inspection device 53 can be configured to measure, for example, the shape dimensions and surface roughness of the wafer 1, particularly, the shape dimensions and surface roughness of the outer circumferential portion 2 of the wafer 1. Preferably, the shape inspection device 53 is of a noncontact type. For example, as the shape inspection device 53, any shape inspection device can be used, such as LEP series (registered trademark) manufactured by KOBELCO research institute, LJ-X series (registered trademark) manufactured by KEYENCE CORPORATION, and Opt-scope (registered trademark) manufactured by TOKYO SEIMITSU CO., LTD.

The crystal inspection device 54 can be configured to inspect the crystal structure of the wafer 1, particularly, the crystal structure of the outer circumferential portion 2 of the wafer 1, for example, by Raman spectroscopic observation, X-ray 3D topography, or X-ray diffraction (XRD).

Furthermore, the grinding apparatus 100 can include a conveyance device 55 capable of conveying the wafer 1. The conveyance device 55 can convey the wafer 1 between the swiveling device 40, the surface inspection device 52, and the shape inspection device 53 and/or the crystal inspection device 54. For example, the conveyance device 55 as above can be configured to convey the wafer 1 using an arm (not illustrated) capable of grasping the wafer 1.

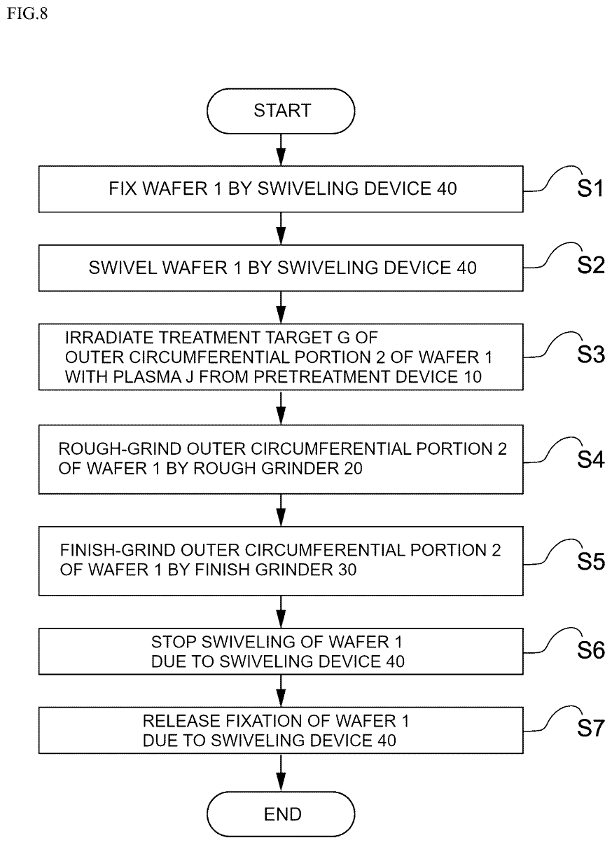

A grinding method using the grinding apparatus 100 according to the present embodiment will be described with reference to FIG. 8. First, a wafer 1 is fixed to the fastener 42 of the swiveling mechanism 41 of the swiveling device 40 (step S1). At this time, the controller 50 can control the fastener 42 such that the wafer 1 is kept fixed. The wafer 1 is swiveled by the driver 43 of the swiveling mechanism 41 and is kept swiveled (step S2).

The treatment target G of the outer circumferential portion 2 of the wafer 1, which is kept swiveled, is irradiated with the plasma J from each plasma generator 10a of the pretreatment device 10 (step S3). The outer circumferential portion 2 of the wafer 1, which is kept swiveled, after irradiation with the plasma J is rough-ground by the grinding wheel 21 of the rough grinder 20 swiveling counter to the swiveling of the wafer 1 (step S4).

The outer circumferential portion 2 of the wafer 1, which is kept swiveled, after rough grinding is finish-ground by the grinding wheel 31 of the finish grinder 30 swiveling counter to the swiveling of the wafer 1 (step S5). The swiveling of the wafer 1 due to the driver 43 is stopped (step S6). The fastener 42 releases the fixation of the wafer 1 after finish grinding (step S7). At this time, the controller 50 can control the fastener 42 such that the fixation of the wafer 1 is released.

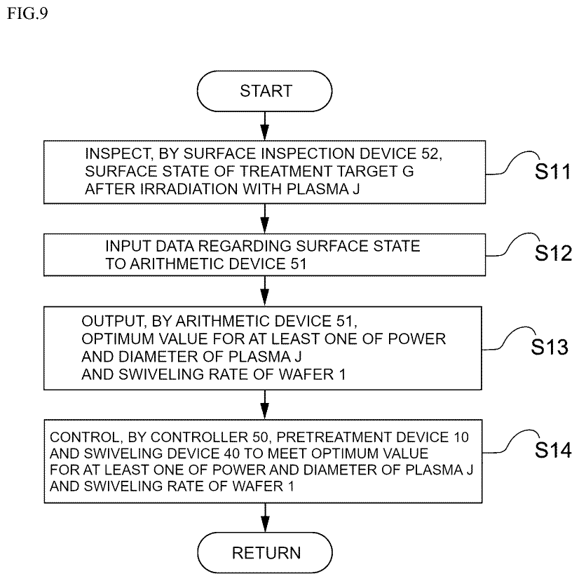

A method for optimizing the condition for irradiation with the plasma J by the pretreatment device 10 in the grinding apparatus 100 according to the present embodiment will be described with reference to FIG. 9. The surface inspection device 52 inspects a plurality of surface states of the treatment target G of the wafer 1 after irradiation with plasma J (step S11). Data regarding the surface states obtained by this inspection is input to the arithmetic device 51 (step S12).

On the basis of the input data regarding the surface states, the arithmetic device 51 calculates and outputs an optimum value for at least one of the power and diameter of the plasma J and the swiveling rate of the wafer 1 (step S13). The controller 50 controls the pretreatment device 10 and the swiveling device 40 to meet the output optimum value for at least one of the power and diameter of the plasma J and the swiveling rate of the wafer 1 (step S14).

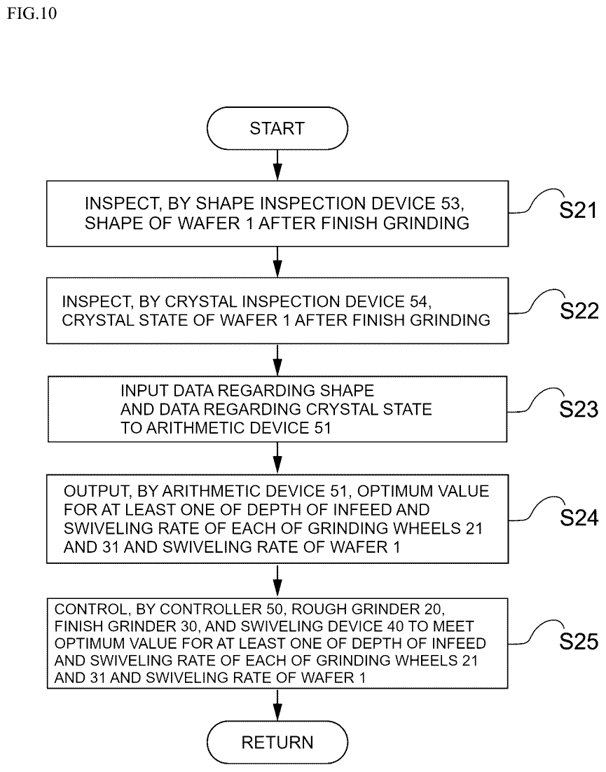

A method for optimizing the condition for grinding by the grinders in the grinding apparatus 100 according to the present embodiment will be described with reference to FIG. 10. The shape inspection device 53 inspects a plurality of shapes of the wafer 1 after finish grinding (step S21). The crystal inspection device 54 inspects a plurality of crystal states of the wafer 1 after finish grinding (step S22). Data regarding the shapes and data regarding the crystal states obtained by these inspections are input to the arithmetic device 51 (step S23).

On the basis of the input data regarding the shapes and data regarding the crystal states, the arithmetic device 51 calculates and outputs an optimum value for at least one of the depth of infeed and swiveling rate of each of the grinding wheels 21 and 31 of the rough grinder 20 and the finish grinder 30 and the swiveling rate of the wafer 1 (step S24). The controller 50 controls the rough grinder 20, the finish grinder 30, and the swiveling device 40 to meet the output optimum value for at least one of the depth of infeed and swiveling rate of each of the grinding wheels 21 and 31 of the rough grinder 20 and the finish grinder 30 and the swiveling rate of the wafer 1 (step S25).

According to the above, the pretreatment device 10 according to the present embodiment includes the plasma generators 10a each capable of irradiating, before the outer circumferential portion 2 of the disk-shaped wafer 1 is ground, the treatment target G, which is at least part of the outer circumferential portion 2 of the wafer 1, with the plasma J to modify the treatment target G.

According to the pretreatment device 10 as above, the treatment target G softens due to irradiation with the plasma J. Thus, the softened outer circumferential portion 2 of the wafer 1 can be efficiently ground in the grinding operation after irradiation with the plasma J.

Furthermore, in grinding the outer circumferential portion 2 including the softened treatment target G in the wafer 1, the grinding wheels 21 and 31 can be inhibited from abrading. As a result, an improvement can be made in the shape accuracy of the wafer 1 shaped by the grinding wheels 21 and 31 as above. Therefore, an improvement can be made in the shape accuracy of the wafer 1 shaped by grinding after pretreatment and an improvement can be made in the efficiency of grinding operation of the wafer 1.

The pretreatment device 10 according to the present embodiment includes the two plasma generators 10a. Each plasma generator 10a includes the nozzle 10c capable of emitting the plasma J outward along its irradiation axis 10b. The wafer 1 is provided as a SiC wafer 1. The outer circumferential portion 2 of the wafer 1 includes the two edge portions 3 located one-to-one at both ends in the direction of the central axis of the wafer 1 as the treatment target G. The nozzles 10c of the two plasma generators 10a are disposed facing one-to-one the two edge portions 3 such that the two edge portions 3 can be irradiated one-to-one with the plasma J from one of the two plasma generators 10a and with the plasma J from the other.

According to the pretreatment device 10 (plasma generators) as above, the edge portions 3, which are sharp in shape, in the outer circumferential portion 2 of the wafer 1 can be each softened due to irradiation with the plasma J. Thus, the softened edge portions 3 of the outer circumferential portion 2 of the wafer 1 can be efficiently ground in the grinding operation after irradiation with the plasma J. Furthermore, in grinding the outer circumferential portion 2 including the softened edge portions 3 in the wafer 1, the grinding wheels 21 and 31 can be inhibited from abrading. As a result, an improvement can be made in the shape accuracy of the wafer 1 shaped by the grinding wheels 21 and 31 as above.

In the pretreatment device 10 according to the present embodiment, each edge portion 3 has a shape identical to a shape to be removed by chamfering. The two plasma generators 10a are mutually spaced in the direction of the central axis of the wafer 1. The nozzle 10c of each plasma generator 10a is disposed with its irradiation axis 10b at an angle such that the entirety of the facing edge portion 3 can be irradiated with the plasma J.

According to the pretreatment device 10 as above, the entirety of each edge portion 3 of the outer circumferential portion 2 of the wafer 1 can be accurately softened due to irradiation of the plasma J. Thus, the outer circumferential portion 2 including the softened edge portions 3 in the wafer 1 can be efficiently ground in the grinding operation of the wafer 1 after irradiation with the plasma J.

The grinding apparatus 100 according to the present embodiment includes the pretreatment device 10 according to the present embodiment, the two grinders capable of grinding the outer circumferential portion 2 of the wafer 1, and the swiveling device 40 for swiveling the wafer 1 around the central axis 1a at the time of pretreatment of the wafer 1 by the pretreatment device 10 or at the time of grinding of the wafer 1 by the grinders. The plasma generators 10a of the pretreatment device 10 are each capable of irradiating, with the plasma J, the treatment target G that moves in the circumferential direction of the wafer 1 due to swiveling of the wafer 1 around the central axis 1a. One of the grinders and the other include, respectively, the grinding wheel 21 and the grinding wheel 31 capable of grinding the outer circumferential portion 2 of the wafer 1 that moves from one side to the other side in the circumferential direction of the wafer 1 due to swiveling of the wafer 1, and the driver 22 and the driver 32 capable of swiveling, respectively, the grinding wheel 21 and the grinding wheel 31 counter to the movement of the wafer 1.

According to the grinding apparatus as above, an improvement can be made in the shape accuracy of the wafer 1 shaped due to grinding by the two grinders after pretreatment by the above-described pretreatment device 10, and an improvement can be made in the efficiency of grinding operation of the wafer 1.

The grinding apparatus 100 according to the present embodiment includes the controller 50 capable of controlling the pretreatment device 10, the grinders, and the swiveling device 40, and the arithmetic device 51 capable of calculating at least either an optimum condition for irradiation with the plasma J by the pretreatment device 10 or an optimum condition for grinding by the grinders. The controller 50 is capable of controlling at least one of the pretreatment device 10, the grinders, and the swiveling device 40 to meet at least either the optimum condition for irradiation with the plasma J or the optimum condition for grinding, calculated by the arithmetic device 51.

According to the grinding apparatus 100 as above, the condition for irradiating the treatment target G with the plasma J by the pretreatment device 10 can be optimized to accurately soften the entire treatment target G, and the condition for grinding the wafer 1 by the grinders can be optimized to make an improvement in the shape accuracy of the wafer 1 shaped by grinding.

The grinding apparatus 100 according to the present embodiment includes the surface inspection device 52 capable of inspecting the surface state of the treatment target G modified by the pretreatment device 10. The arithmetic device 51 is capable of calculating an optimum value for at least one of the power and diameter of the plasma J and the swiveling rate of the wafer 1, on the basis of data regarding the surface state of the treatment target G obtained by the surface inspection device 52 as the optimum condition for irradiation with the plasma J. The controller 50 is capable of controlling the pretreatment device 10 and the swiveling device 40 to meet the optimum value for at least one of the power and diameter of the plasma J and the swiveling rate of the wafer 1, calculated by the arithmetic device 51.

According to the grinding apparatus 100 as above, at least one of the power and diameter of the plasma J with which the treatment target G is irradiated by the pretreatment device 10 and the swiveling rate of the wafer 1 can be optimized to accurately soften the entire treatment target G.

The grinding apparatus 100 according to the present embodiment includes at least either the shape inspection device 53 capable of inspecting the shape of the wafer 1 ground by the grinders or the crystal inspection device 54 capable of inspecting the crystal state of the wafer 1 ground by the grinders. The arithmetic device 51 is capable of calculating an optimum value for at least one of the depth of infeed and swiveling rate of each of the grinding wheels 21 and 31 and the swiveling rate of the wafer 1, on the basis of at least either data regarding the shape of the wafer 1 obtained by the shape inspection device 53 or data regarding the crystal state of the wafer 1 obtained by the crystal inspection device 54 as the optimum condition for grinding. The controller 50 is capable of controlling the grinders and the swiveling device 40 to meet the optimum value for at least one of the depth of infeed and swiveling rate of each of the grinding wheels 21 and 31 and the swiveling rate of the wafer 1, calculated by the arithmetic device 51.

According to the grinding apparatus 100 as above, at least one of the depth of infeed and swiveling rate of each of the grinding wheels 21 and 31 in the grinders and the swiveling rate of the wafer 1 can be optimized to make an improvement in the shape accuracy of the wafer 1 shaped due to grinding by the grinders.

In the grinding apparatus 100 according to the present embodiment, the swiveling device 40 includes the swiveling mechanism 41 that swivels the wafer 1 around the central axis 1a at a certain position at the time of pretreatment of the wafer 1 by the pretreatment device 10 or at the time of grinding of the wafer 1 by the grinders. The pretreatment device 10 is disposed on one side in the circumferential direction of the wafer 1 with respect to the grinders.

The grinding apparatus 100 as above enables smooth and efficient performance of a series of steps in which the treatment target G of the outer circumferential portion 2 of the wafer 1 is softened due to the plasma J from the pretreatment device 10 and then the outer circumferential portion 2 including the softened treatment target G in the wafer 1 is ground by the grinders.

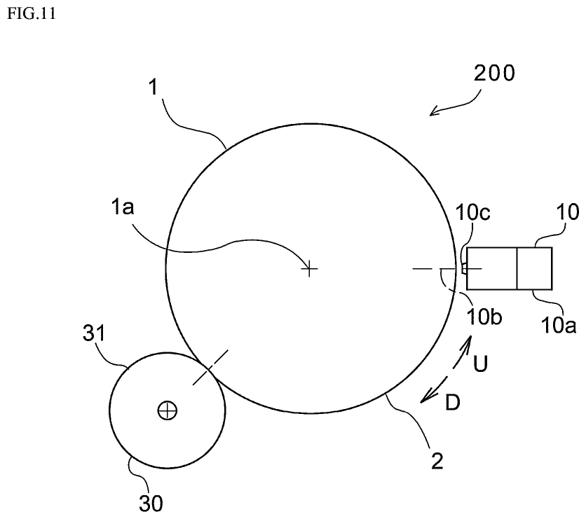

A grinding apparatus 200 according to a second embodiment will be described below with reference to FIG. 11. A pretreatment device 10 included in the grinding apparatus 200 is similar to the pretreatment device 10 included in the grinding apparatus 100 according to the first embodiment. The grinding apparatus 200 according to the present embodiment is similar to the grinding apparatus 100 according to the first embodiment except that no rough grinder 20 is provided.

A grinding method using the grinding apparatus 200 according to the present embodiment is different from the grinding method using the grinding apparatus 100 according to the first embodiment in that no step S4 regarding rough grinding is included and no rough grinder 20 is used. In such a grinding method, a treatment target G of an outer circumferential portion 2 of a wafer 1 that is kept swiveled is irradiated with plasma J from each plasma generator 10a of the pretreatment device 10 and then the outer circumferential portion 2 of the wafer 1, which is kept swiveled, after irradiation with the plasma J is finish-ground by a grinding wheel 31 of a finish grinder 30 swiveling counter to the swiveling of the wafer 1. In other aspects, the grinding method according to the present embodiment is similar to the grinding method according to the first embodiment.

In the grinding apparatus according to the present embodiment, a method for optimizing the condition for irradiation with the plasma J by the pretreatment device 10 can be performed, similarly to the first embodiment, and a method for optimizing the condition for grinding by the finish grinder 30 can be performed, similarly to the first embodiment.

As described above, the grinding apparatus 200 according to the present embodiment can bring about operations and effects similar to those of the grinding apparatus 100 according to the first embodiment.

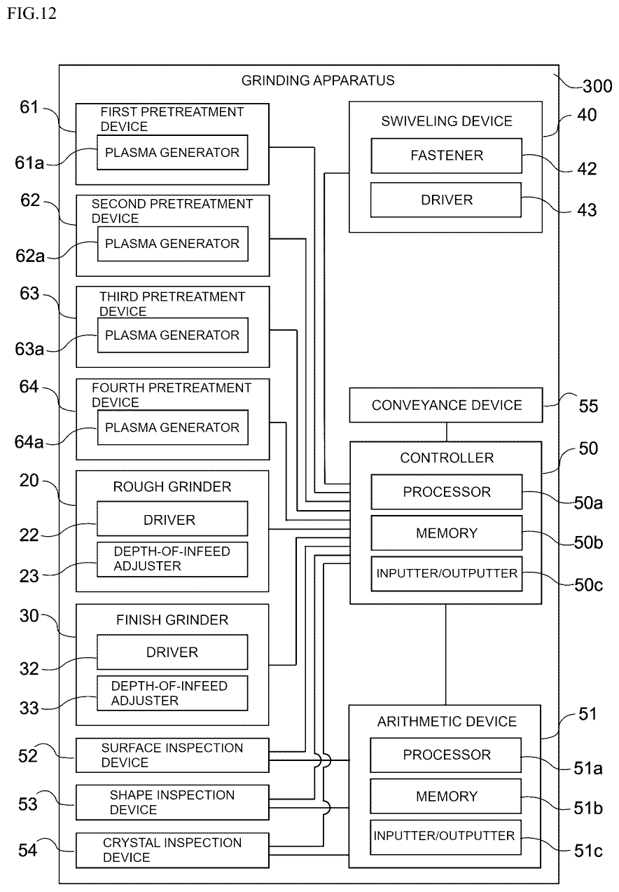

A grinding apparatus 300 according to a third embodiment will be described with reference to FIGS. 12 to 14. The grinding apparatus 300 includes first to fourth pretreatment devices 61, 62, 63, and 64. As illustrated in FIG. 12, the grinding apparatus 300 according to the present embodiment is similar to the grinding apparatus 100 according to the first embodiment except that a plurality of pretreatment devices (first to fourth pretreatment devices 61, 62, 63, and 64) are mutually spaced in the circumferential direction of a wafer 1.

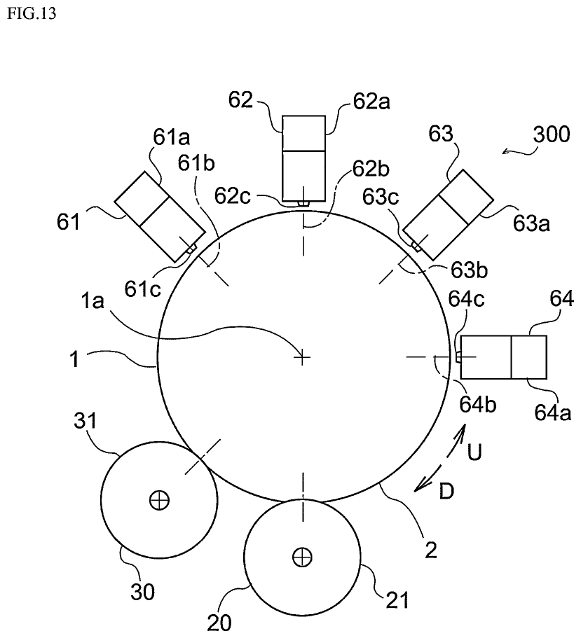

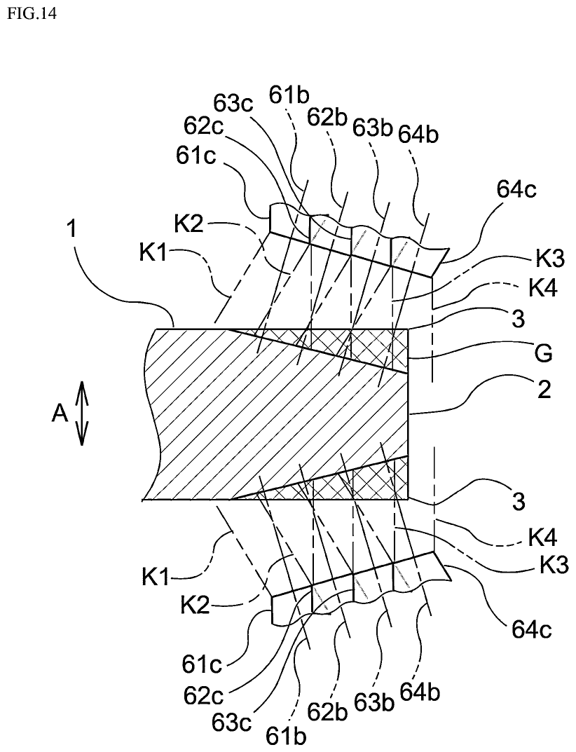

As illustrated in FIGS. 13 and 14, the pretreatment devices (first to fourth pretreatment devices 61 to 64) included in the grinding apparatus 300 are roughly configured like the pretreatment device 10 included in the grinding apparatus 100 according to the first embodiment. The pretreatment devices (first to fourth pretreatment devices 61 to 64) as above include plasma generators 61a, 62a, 63a, and 64a capable of irradiating a treatment target G with plasma K1, plasma K2, plasma K3, and plasma K4, respectively, to modify the treatment target G. The plasma generators 61a to 64a include nozzles 61c, 62c, 63c, and 64c capable of emitting the plasma K1, the plasma K2, the plasma K3, and the plasma K4 outward along irradiation axes 61b, 62b, 63b, and 64b, respectively.

As illustrated in FIG. 14, the nozzles 61c to 64c of the plasma generators 61a to 64a in the pretreatment devices (first to fourth pretreatment devices 61 to 64) are disposed differently from each other in the radial direction of a wafer 1 such that the entirety of a facing edge portion 3 of an outer circumferential portion 2 of the wafer 1 can be irradiated with the respective plasma K1, plasma K2, plasma K3, and plasma K4 emitted from the nozzles 61c to 64c. The plasma generators 61a to 64a as above can be configured not to perform such raster scanning as described above.

A grinding method using the grinding apparatus 300 according to the present embodiment is similar to the grinding method using the grinding apparatus 300 according to the first embodiment except that the pretreatment devices (first to fourth pretreatment devices 61 to 64) are used. The grinding apparatus 100 according to the present embodiment can perform a method for optimizing the condition for irradiation with the plasma K1, the plasma K2, the plasma K3, and the plasma K4 by the pretreatment devices (first to fourth pretreatment devices 61 to 64), similarly to the first embodiment, and can perform a method for optimizing the condition for grinding by grinders, similarly to the first embodiment.

Note that FIG. 13 illustrates, as an example, the grinder including four pretreatment devices (first to fourth pretreatment devices 61 to 64), namely, the first pretreatment device 61, the second pretreatment device 62, the third pretreatment device 63, and the fourth pretreatment device 64. However, the grinding apparatus can include two, three, or five or more pretreatment devices.

As described above, the grinding apparatus 300 according to the present embodiment can bring about operations and effects similar to those of the grinding apparatus 100 according to the first embodiment.

Furthermore, the grinding apparatus 300 according to the present embodiment includes the pretreatment devices (first to fourth pretreatment devices 61 to 64) mutually spaced in the circumferential direction of the wafer 1. Thus, the entirety of the treatment target G can be efficiently softened due to irradiation with the plasma K1, the plasma K2, the plasma K3, and the plasma K4.

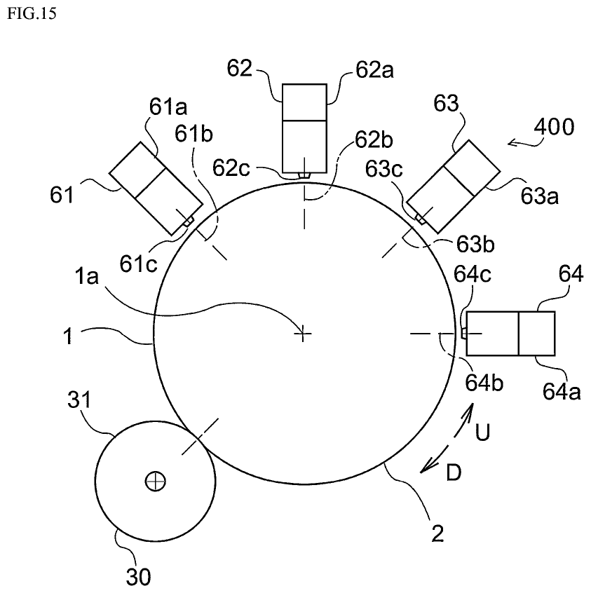

Pretreatment devices (first to fourth pretreatment devices 61 to 64) and a grinding apparatus according to a fourth embodiment will be described below with reference to FIG. 15. The pretreatment devices (first to fourth pretreatment devices 61 to 64) included in the grinding apparatus according to the present embodiment are similar to the pretreatment devices (first to fourth pretreatment devices 61 to 64) included in the grinding apparatus according to the third embodiment. A grinding apparatus 400 according to the present embodiment is similar to the grinding apparatus 300 according to the third embodiment except that no rough grinder 20 is provided.

Note that the grinding apparatus can include two, three, or five or more pretreatment devices.

A grinding method using the grinding apparatus 400 according to the present embodiment is different from the grinding method using the grinding apparatus 300 according to the third embodiment in that no step regarding rough grinding is included and no rough grinder 20 is used. In such a grinding method, a treatment target G of an outer circumferential portion 2 of a wafer 1 that is kept swiveled is irradiated with plasma K1, plasma K2, plasma K3, and plasma K4 from plasma generators 61a to 64a of the pretreatment devices (first to fourth pretreatment devices 61 to 64) and then the outer circumferential portion 2 of the wafer 1, which is kept swiveled, after irradiation with the plasma K1, the plasma K2, the plasma K3, and the plasma K4 is finish-ground by a grinding wheel 31 of a finish grinder 30 swiveling counter to the swiveling of the wafer 1. In other aspects, the grinding method according to the present embodiment is similar to the grinding method according to the third embodiment.

In the grinding apparatus 400 according to the present embodiment, a method for optimizing the condition for irradiation with the plasma K1, the plasma K2, the plasma K3, and the plasma K4 by the pretreatment devices (first to fourth pretreatment devices 61 to 64) can be performed, similarly to the third embodiment, and a method for optimizing the condition for grinding by the finish grinder can be performed, similarly to the first embodiment.

As described above, the grinding apparatus 400 according to the present embodiment can bring about operations and effects similar to those of the grinding apparatus 300 according to the third embodiment.

Although the embodiments of the present invention have been described above, the present invention is not limited to the embodiments described above. Thus, modifications and alterations can be made on the basis of the technical idea of the present invention.

A grinding apparatus according to the present invention enables an improvement in the shape accuracy of a wafer shaped due to the grinding operation and an improvement in the efficiency of grinding operation of a wafer.

What is claimed is:

1. A grinding apparatus comprising at least one plasma generator configured to irradiate, before an outer circumferential edge of a wafer is ground, at least part of the outer circumferential edge with plasma.

2. The grinding apparatus according to claim 1, wherein
the plasma generator includes a plurality of plasma generators,
the plasma generators each includes a nozzle configured to emit the plasma, and
the nozzles of the plasma generators face two edge portions in a thickness direction of the outer circumferential edge of the wafer in one-to-one correspondence to irradiate the two edge portions with the plasma.

3. The grinding apparatus according to claim 2, wherein the nozzles of the plasma generators are each provided inclinably.

4. The grinding apparatus according to claim 1, further comprising:
a swiveling device for swiveling the wafer around a central axis of the wafer; and
a grinder including a grinding wheel configured to grind an outer circumferential portion of the wafer, and a driver configured to swivel the grinding wheel, wherein
the plasma generator is capable of irradiating, with the plasma, a pretreatment target that moves in a circumferential direction of the wafer due to swiveling of the wafer around the central axis.

5. The grinding apparatus according to claim 4, further comprising:
a controller; and
an arithmetic device capable of calculating at least either an optimum condition for irradiation with the plasma by the plasma generator or an optimum condition for grinding by the grinder, wherein
the controller is capable of controlling at least one of the plasma generator and the grinder to meet at least either the optimum condition for irradiation with the plasma or the optimum condition for grinding, calculated by the arithmetic device.

6. The grinding apparatus according to claim 5, further comprising a surface inspection device capable of inspecting a surface state of the wafer, wherein
the arithmetic device is capable of calculating, as the optimum condition for irradiation with the plasma, an optimum value for at least one of a diameter and power of the plasma and a swiveling rate of the wafer, based on data regarding the surface state, and
the controller is capable of controlling the plasma generator and the swiveling device to meet the optimum value.

7. The grinding apparatus according to claim 5, further comprising at least either a shape inspection device capable of inspecting a shape of the wafer or a crystal inspection device capable of inspecting a crystal state of the wafer, wherein
the arithmetic device is capable of calculating, as the optimum condition for grinding, an optimum value for at least one of a depth of infeed and a swiveling rate of the grinding wheel and a swiveling rate of the wafer, based on at least either the shape or the crystal state, and
the controller is capable of controlling the grinder and the swiveling device to meet the optimum value.

8. The grinding apparatus according to claim 4, comprising the plasma generators mutually spaced in a circumferential direction of the wafer.
